(19) United States
(12) Patent Application Publication
(10) Pub. No.: US 2014/0131727 A1
(43) Pub. Date: May 15, 2014

(54) LIGHT EMITTING DIODE CHIP AND METHOD FOR MANUFACTURING THE SAME

(71) Applicant: ADVANCED OPTOELECTRONIC TECHNOLOGY, INC., Hsinchu Hsien (TW)

(72) Inventors: CHING-HSUEH CHIU, Hsinchu (TW); YA-WEN LIN, Hsinchu (TW); PO-MIN TU, Hsinchu (TW); SHIH-CHENG HUANG, Hsinchu (TW)

(73) Assignee: ADVANCED OPTOELECTRONIC TECHNOLOGY, INC., Hsinchu Hsien (TW)

(21) Appl. No.: 14/014,371

(22) Filed: Aug. 30, 2013

(30) Foreign Application Priority Data
Nov. 12, 2012 (CN) 201210449845X

(51) Int. Cl. H01L 33/10; H01L 33/00

(52) U.S. Cl. CPC H01L 33/10; H01L 33/0075
USPC 257/76; 438/32

(57) ABSTRACT

A method for manufacturing a light emitting diode chip includes following steps: providing a sapphire substrate, the sapphire substrate having a plurality of protrusions on an upper surface thereof; forming an un-doped GaN layer on the upper surface of the sapphire substrate, the un-doped GaN layer having an upper part covering top ends of the protrusions; forming a distributed bragg reflective layer on the un-doped GaN layer until the distributed bragg reflective layer totally covering the protrusions and the un-doped GaN layer; etching the distributed bragg reflective layer and the upper part of the un-doped GaN layer to expose the top ends of the protrusions; and forming an n-type GaN layer, an active layer, and a p-type GaN layer sequentially on the top ends of the protrusions and the distributed bragg reflective layer. An LED chip formed by the method described above is also provided.

### BACKGROUND

1. Technical Field

The disclosure generally relates to a light emitting diode (LED) chip, and a method for manufacturing the LED chip, wherein the lattice dislocations and defects are lowered whereby light extraction efficiency is increased.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In epitaxial growth of an LED chip, one problem is how to reduce lattice defects in the semiconductor layers. One way to reduce the lattice defects is to provide a pattered sapphire substrate. By forming a plurality of protrusions on the sapphire substrate, semiconductor layers will be laterally grown from the protrusions, thereby reducing the lattice defects in the semiconductor layers. However, in the process described above, the semiconductor layer directly grows from a bottom of the protrusions will still have lattice defects, and the lattice defects are easy to concentrate on a top side of the protrusions to affect growth of following semiconductor layers.

What is needed, therefore, is an LED chip and a method for manufacturing the LED chip to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 shows a first step of a method for manufacturing an LED chip in accordance with an embodiment of the present disclosure.

FIG. 2 shows a second step of the method for manufacturing an LED chip in accordance with an embodiment of the present disclosure.

FIG. 3 shows a third step of the method for manufacturing an LED chip in accordance with an embodiment of the present disclosure.

FIG. 4 shows a fourth step of the method for manufacturing an LED chip in accordance with an embodiment of the present disclosure.

FIG. 5 shows a fifth step of the method for manufacturing an LED chip in accordance with an embodiment of the present disclosure.

FIG. 6 shows light paths of the LED chip in FIG. 5.

### DETAILED DESCRIPTION

An embodiment of an LED chip and a method for manufacturing the LED chip will now be described in detail below and with reference to the drawings.

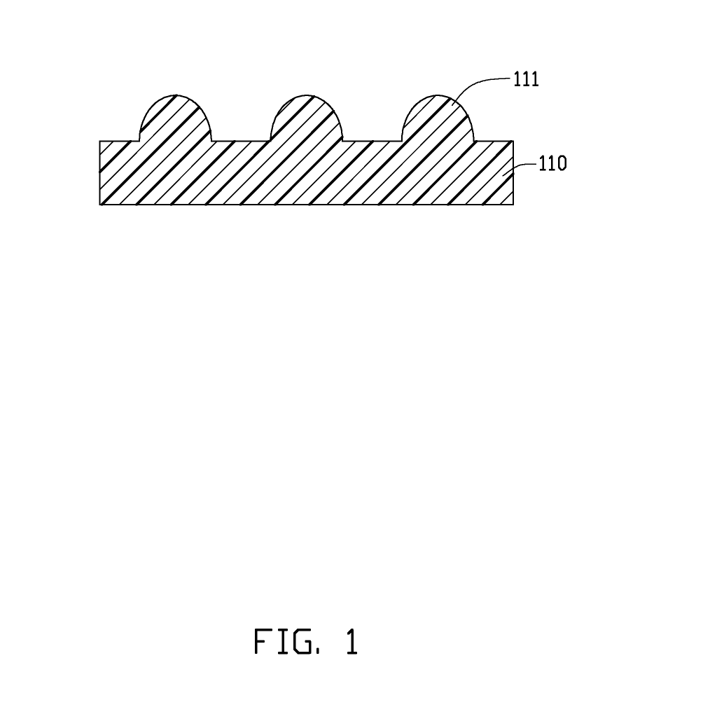

Referring to FIG. 1, a sapphire substrate 110 with a plurality of protrusions 111 is first provided. The sapphire substrate 110 is a patterned sapphire substrate. A cross sectional of the sapphire substrate 110 is rectangular. The sapphire substrate 110 has an upper surface and a bottom surface opposite to the upper surface. The protrusions 111 are formed on the upper surface of the sapphire substrate 110. In this embodiment, each protrusion 111 has a semi-circular cross section. In alternative embodiments, the cross section of each of the protrusions 111 can be triangular, trapezoid, or other polygons.

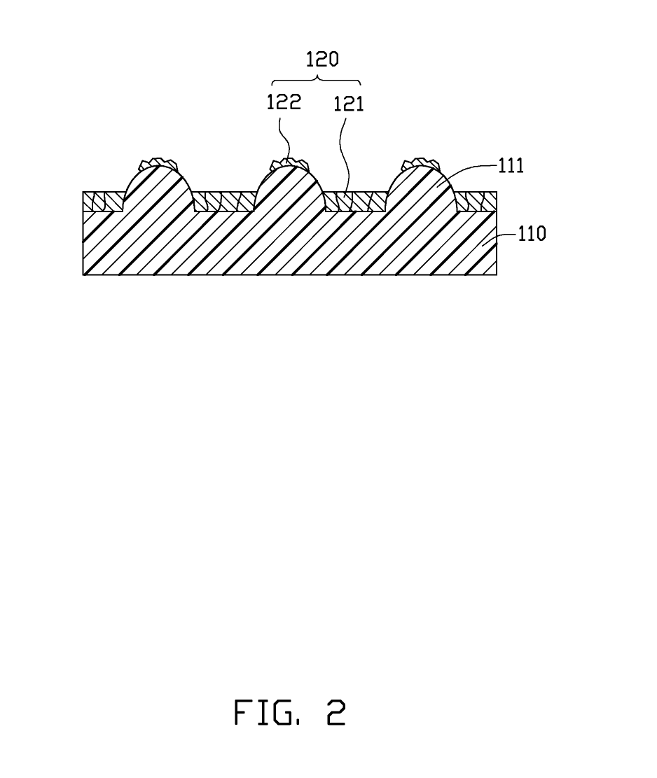

Referring to FIG. 2, an un-doped GaN layer 120 is formed on the upper surface of the sapphire substrate 110 having the protrusions 111. The un-doped GaN layer 120 partly covers the protrusions 111 to expose parts of the protrusions 111. In this embodiment, the un-doped GaN layer 120 includes a first portion 121 located between two protrusions 111 and a second portion 122 located on a top end of each of the protrusions 111.

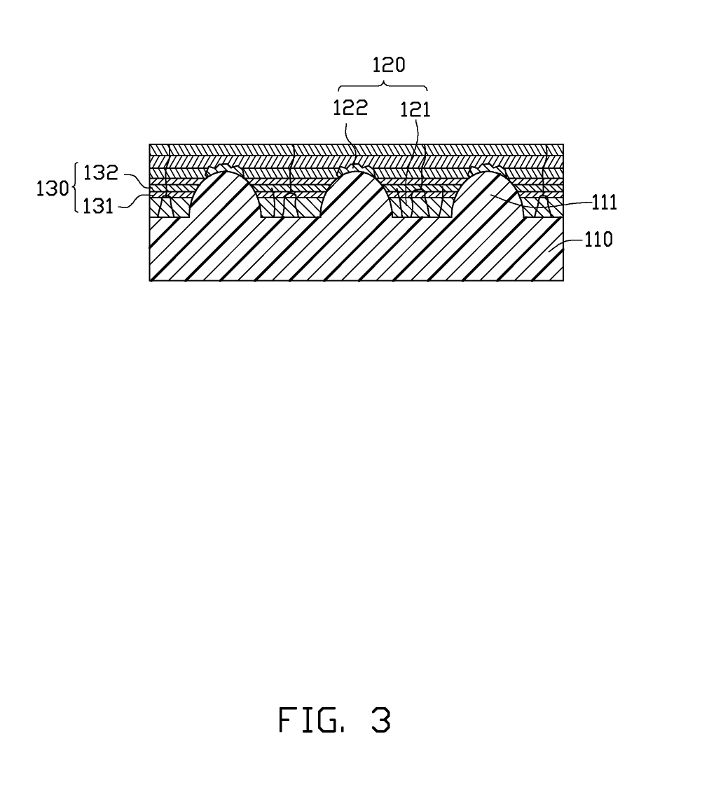

Referring to FIG. 3, a distributed bragg reflective (DBR) layer 130 is formed on the un-doped GaN layer 120 until the distributed bragg reflective layer 130 totally covers the exposing parts of the protrusions 111. The distributed bragg reflective layer 130 consists of a plurality of pairs of layers with different refractive indices stacked on the un-doped GaN layer along a direction away from the un-doped GaN layer. In this embodiment, each pair of layers of the distributed bragg reflective layer 130 includes an AlN layer 131 and a GaN layer 132. The AlN layers 131 and the GaN layers 132 are alternately formed on each other along a direction away from the un-doped GaN layer 120. Preferably, the distributed bragg reflective layer 130 is grown until it totally covers the second portion 122 of the un-doped GaN layer 120.

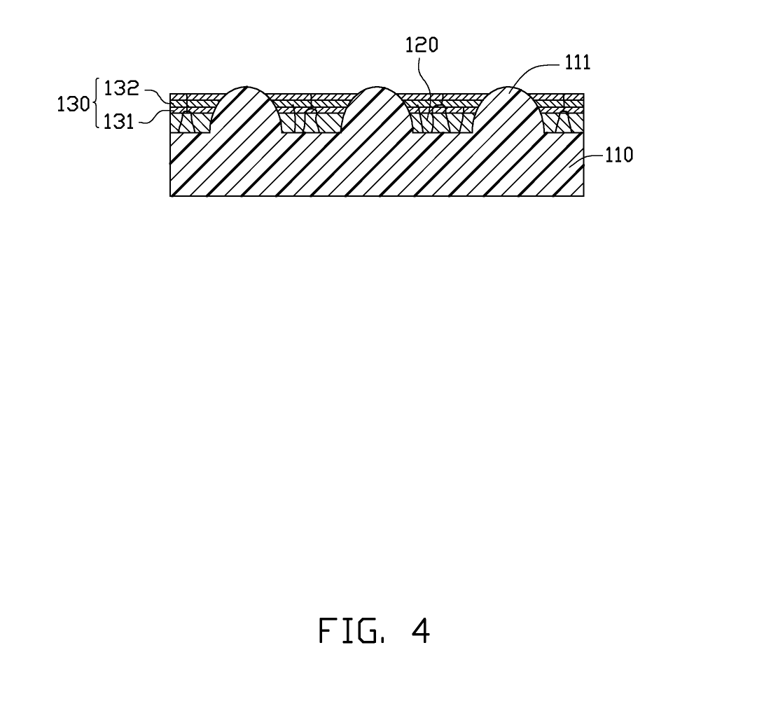

Referring to FIG. 4, the distributed bragg reflective layer 130 and the un-doped GaN layer 120 are etched to expose the top ends of the protrusions 111. The distributed bragg reflective layer 130 and the un-doped GaN layer 120 can be etched by wet etching process or by dry etching process. In this embodiment, the distributed bragg reflective layer 130 and the un-doped GaN layer 120 are etched by inductively coupled plasma etching. Preferably, when the top ends of the protrusions 111 are exposed, the distributed bragg reflective layer 130 and the un-doped GaN layer 120 are continuously to be etched until the second portion 122 of the un-doped GaN layer 120 is totally etched away. The un-doped GaN layer 120 is also totally etched away. A part (i.e., three constituting layers) of the distributed reflective layer 130 is left after the etching process.

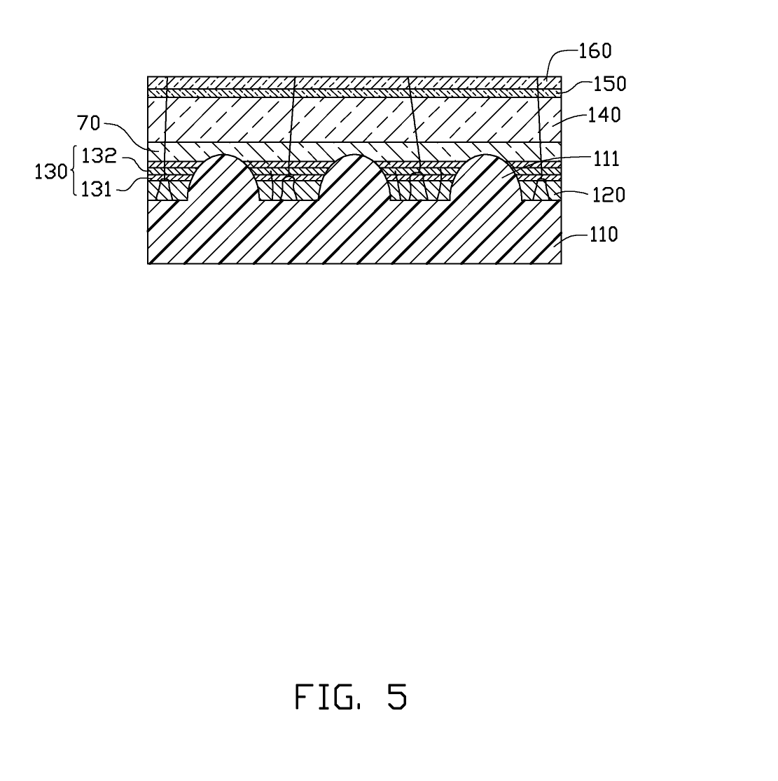

Referring to FIG. 5, an n-type GaN layer 140, an active layer 150, and a p-type GaN layer 160 are sequentially formed on the top end of the protrusion 111 and the distributed bragg reflective layer 130. In this embodiment, the active layer 150 is multiple quantum well (MQW) layer. Preferably, before the forming of the n-type GaN layer 140, an un-doped GaN layer 70 is formed on the top end of the protrusion 111 and the distributed bragg reflective layer 130. Then, the n-type GaN layer 140, the active layer 150, and the p-type GaN layer 160 are sequentially formed on the un-doped GaN layer 70.

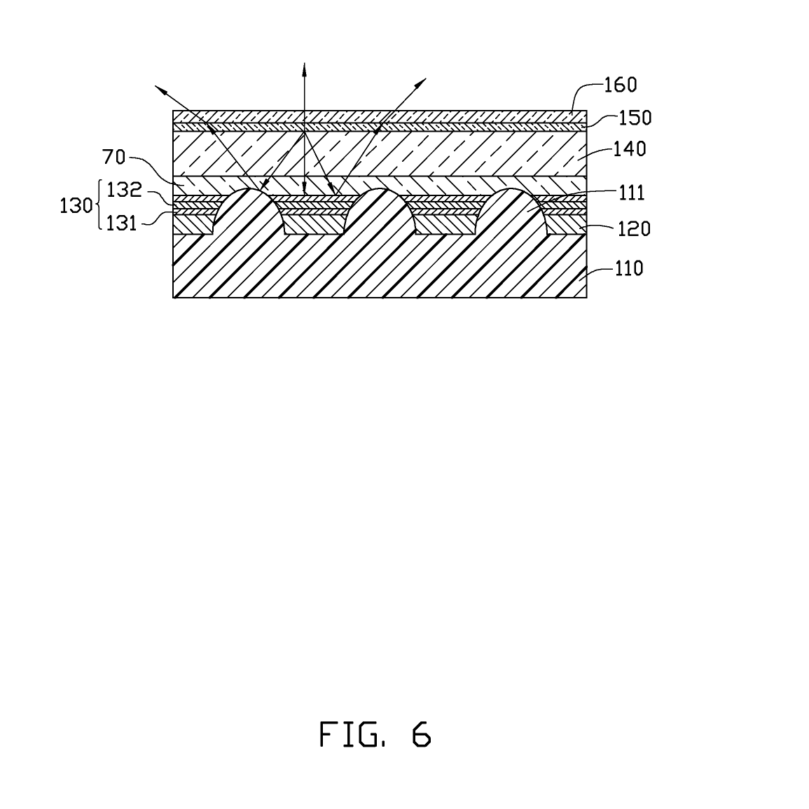

In the method for manufacturing LED chip described above, the distributed bragg reflective layer 130 is formed between two adjacent protrusions 111 of the sapphire substrate 110. The distributed bragg reflective layer 130 can prevent lattice defects in the first portion 121 of the un-doped GaN layer 120 from extending upwardly to the n-type GaN layer 140, the active layer 150, and the p-type GaN layer 160. Therefore, the lattice qualities of the n-type GaN layer 140, the active layer 150, and the p-type GaN layer 160 are improved. In addition, since lattice defects will concentrate on the second portion 122 of the un-doped GaN layer 120, after the second portion 122 of the un-doped GaN layer 120 is etched away, the lattice defects in the second portion 122 of the un-doped GaN layer 120 are also etched away and will not extend upwardly to affect the lattice qualities of the n-type GaN layer 140, the active layer 150, and the p-type GaN layer 160. Furthermore, the distributed bragg reflective layer 130 can also improve lighting efficiency of the LED chip. Referring to FIG. 6, since the distributed bragg reflective layer 130 is formed between two adjacent protrusions 111, light from the active layer 150 emitting to the sapphire substrate 110 will be reflected by the distributed bragg reflective layer 130 and emits into outer environment. Therefore, the distributed bragg reflective layer 130 prevents light from being absorbed by the un-doped GaN layer 120 or the sapphire substrate 110, and improves lighting efficiency of the LED chip.

An LED chip formed by the method described above is also provided. Referring to FIG. 5, the LED chip includes a sapphire substrate 110, an un-doped GaN layer 120 formed on an upper surface of the sapphire substrate 110, a distributed bragg reflective layer 130 formed on the un-doped GaN layer 120, and an un-doped GaN layer 70, an n-type GaN layer 140, an active layer 150, and a p-type GaN layer 160 formed on the distributed bragg reflective layer 130. A plurality of protrusions 111 are formed on the upper surface of the sapphire substrate 110. The un-doped GaN layer 120 and the distributed bragg reflective layer 130 are formed between two adjacent protrusions 111. A level of an upper surface of the distributed bragg reflective layer 130 is lower than a level of the top ends of the protrusions 111. In an alternative embodiment, the n-type GaN layer 140, the active layer 150, and the p-type GaN layer 160 can be directly formed on the upper surface of the protrusions 111 and the distributed bragg reflective layer 130. Since the distributed bragg reflective layer 130 is formed between two adjacent protrusions 111 of the sapphire substrate 110, the distributed bragg reflective layer 130 can prevent lattice defects in the first portion 121 of the un-doped GaN layer 120 from extending upwardly to the n-type GaN layer 140, the active layer 150, and the p-type GaN layer 160. Therefore, the lattice qualities of the n-type GaN layer 140, the active layer 150, and the p-type GaN layer 160 are improved.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing a light emitting diode chip, comprising:
providing a sapphire substrate, the sapphire substrate having a plurality of protrusions on an upper surface thereof;
forming an un-doped GaN layer on the upper surface of the sapphire substrate, the un-doped GaN layer having an upper part covering top ends of the protrusions to expose parts of the protrusions;
forming a distributed bragg reflective layer on a lower part of the un-doped GaN layer until the distributed bragg reflective layer covering the exposed parts of the protrusions and the upper part of the un-doped GaN layer on the top ends of the protrusions;
etching the distributed bragg reflective layer and the upper part of un-doped GaN layer on the top ends of the protrusions to expose the top ends of the protrusions; and
forming an n-type GaN layer, an active layer, and a p-type GaN layer sequentially on the top ends of the protrusions and a remained portion of the distributed bragg reflective layer after the etching process.

2. The method of claim 1, wherein the distributed bragg reflective layer comprises a plurality of pairs of layers with different refractive indices formed on the lower part of the un-doped GaN layer along a direction away from the lower part of the un-doped GaN layer.

3. The method of claim 2, wherein each pair of layers of the distributed bragg reflective layer comprises an AlN layer and a GaN layer, the AlN layers and GaN layers are alternately stacked on each other along a direction away from the lower part of the un-doped GaN layer.

4. The method of claim 1, wherein the distributed bragg reflective layer and the upper part of the un-doped GaN layer are etched by dry etching or wet etching.

5. The method of claim 4, wherein the distributed bragg reflective layer and the upper part of the un-doped GaN layer are are etched by inductively coupled plasma etching.

6. The method of claim 1, wherein the active layer is a multiple quantum well layer.

7. The method of claim 1, wherein the protrusions each have a semi-circular, triangular or trapezoid cross section.

8. The method of claim 1, wherein before forming the n-type GaN layer on the upper ends of the protrusions and the distributed bragg reflective layer, an additional un-doped GaN layer is formed on the upper ends of the protrusions and the distributed bragg reflective layer, and then the n-type GaN layer, the active layer, and the p-type GaN layer are sequentially formed on the additional un-doped GaN layer.

9. A light emitting diode chip, comprising:
a sapphire substrate, having a plurality of protrusions on an upper surface thereof;
an un-doped GaN layer, formed between two adjacent protrusions;
a distributed bragg reflective layer, formed on the un-doped GaN layer, a level of an upper surface of the distributed bragg reflective layer being lower than a level of a top end of each of the protrusions; and
an n-type GaN layer, an active layer, and a p-type GaN layer, formed sequentially on the top ends of the protrusions and the distributed bragg reflective layer.

10. The light emitting diode chip of claim 9, wherein the distributed bragg reflective layer comprises at least two layers with different refractive indices stacked on each other along a direction away from the un-doped GaN layer.

11. The light emitting diode chip of claim 10, wherein the at least two layers of the distributed bragg reflective layer comprise an AlN layer and a GaN layer.

12. The light emitting diode chip of claim 9, wherein the active layer is a multiple quantum well layer.

13. The light emitting diode chip of claim 9, wherein the protrusions each have a semi-circular, triangular or trapezoid cross section.

14. The light emitting diode chip of claim 9, further comprising an additional un-doped GaN layer formed on the upper ends of the protrusions and the distributed bragg reflective layer, and the n-type GaN layer, the active layer, and the p-type GaN layer are sequentially formed on the additional un-doped GaN layer.
